(19) United States
(12) Patent Application Publication
(10) Pub. No.: US 2025/0111985 A1
(43) Pub. Date: Apr. 3, 2025

(54) LEAD STRUCTURE FOR AN INDUCTIVE COIL

(71) Applicant: TEXAS INSTRUMENTS INCORPORATED, Dallas, TX (US)

(72) Inventors: Ruby Ann M. CAMENFORTE, PAMPANGA (PH); Charmaine Grace FACAL, OLONGAPO CITY (PH); John Carlo MOLINA, LIMAY (PH); Jason B. COLTE, LA TRINIDAD (PH)

(21) Appl. No.: 18/478,053

(22) Filed: Sep. 29, 2023

(51) Int. Cl. H01F 27/28; H01F 27/29; H01F 41/04; H01L 23/31; H01L 23/495

(52) U.S. Cl. CPC H01F 27/2828; H01F 27/29; H01F 41/04; H01L 23/3107; H01L 23/49551

(57) ABSTRACT

A device that includes a lead structure and a coil is provided. The lead structure, of an electrically conductive material, has a lead structure width. The coil, of the electrically conductive material, includes first and second coil ends and a number of windings of the electrically conductive material extending between the first and second coil ends. The lead structure width is greater than a largest cross sectional dimension of the windings.

### TECHNICAL FIELD

This description relates to a lead structure for an inductive coil.

### BACKGROUND

An inductor is an impedance device, typically including a coil, for introducing inductance to an electronic circuit. As the microelectronic arts (e.g., semiconductor fabrication, integrated circuit (IC) packaging, etc.) have advanced, integration levels and functionality levels have increased so that inductors as well as transistors, resistors, diodes, and capacitors are fabricated in or for use with semiconductor devices. However, existing inductor designs are usually rigid and thus tend to control layout designs for semiconductor devices.

### SUMMARY

A first example relates to a device that includes a lead structure and a coil. The lead structure, of an electrically conductive material, has a lead structure width. The coil, of the electrically conductive material, includes first and second coil ends and a number of windings of the electrically conductive material extending between the first and second coil ends. The lead structure width is greater than a largest cross sectional dimension of the windings.

A second example relates to a circuit. The circuit includes a substrate supporting the circuit. A substrate surface of the substrate defines a plane extending through the substrate. The circuit also includes a terminal. The circuit further includes a lead structure of an electrically conductive material, having a lead structure width, coupled to the terminal. The circuit yet further includes a coil, of the electrically conductive material, having first and second coil ends and a number of windings of the electrically conductive material extending between the first and second coil ends. The first coil end is at a surface of the lead structure. The lead structure width is greater than a largest cross sectional dimension of the windings.

A third example relates to a method for forming a device. The method includes forming a lead structure having a lead structure surface defining plane having a lead structure length and a lead structure width. The method also includes providing a coil, of electrically conductive material, having first and second coil ends and a number of windings of the electrically conductive material extending between the first and second coil ends. The lead structure width and the lead structure length are greater than a largest cross sectional dimension of the windings.

### BRIEF DESCRIPTION OF THE DRAWINGS

FIG. 1A is a top view illustrating an example of a device having lead structures for a coil.

FIG. 1B is a side view of the example device of FIG. 1A.

FIG. 1C is a perspective view illustrating an alternative configuration of the example of a device having lead structures for a coil.

FIG. 2A is a top view illustrating another example of a device having lead structures for a coil.

FIG. 2B is a side view of the example device of FIG. 2A.

FIG. 2C is a perspective view illustrating an alternative configuration of the other example of a device having lead structures for a coil.

FIG. 3 is a side view illustrating an example of a circuit having lead structures at different distances from a longitudinal axis.

FIG. 4 is a side view illustrating another example of a circuit having lead structures at different distances from a longitudinal axis.

FIG. 5 is a side view illustrating an example of a circuit having lead structures at the same distance from a longitudinal axis.

FIG. 6 is a side view illustrating an example of a circuit having a different coil configuration.

FIG. 7 is a perspective view illustrating an example of a packaged circuit having lead structures for a coil.

FIG. 8 is a flowchart illustrating an example method for fabricating a device having lead structures for a coil.

FIG. 9 is a flowchart illustrating an example method for forming a circuit with a device having lead structures for a coil.

FIGS. 10-14B illustrate a device at different stages of a method for forming the circuit.

### DETAILED DESCRIPTION

This description relates to an inductor device having a lead structure and a number of coil windings, such as can be used in a semiconductor device. The lead structure provides a connection to a circuit, such as at a terminal. In some examples, the inductor device includes a first lead structure and a second lead structure connected at a first end of the coil and a second end of the coil, respectively. The first and second lead structures may form connections at different levels (e.g., distances) from and/or orientations with respect to a longitudinal axis extending through the coil. This versatility in design provides increased opportunities for use of inductive coils and provides additional inductor module capabilities such that more components are able to be connected in a single package.

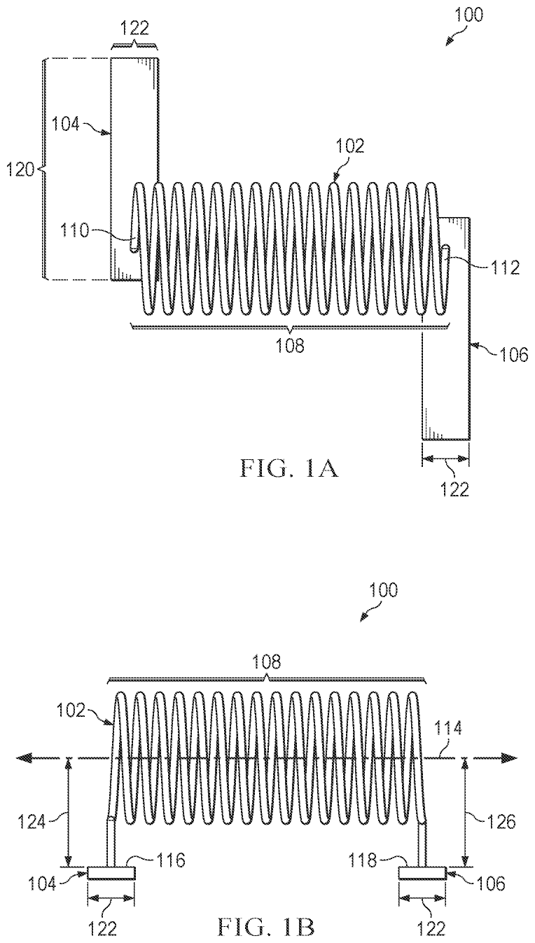

FIG. 1A illustrates an inductor device 100 having a coil 102, a first lead structure 104 and a second lead structure 106. As one example, the coil 102 is an inductor that can be coupled to a microelectronic circuit (not shown) using the first lead structure 104 and/or the second lead structure 106. The coil 102 includes a number of windings 108 arranged between a first coil end 110 and a second coil end 112. The windings 108 are formed of a conductive material, such as copper, palladium, gold, silver, or other appropriate conductive metal or metal alloy with similar electrically conductive properties. In some examples, the windings 108 are coated with an insulator (e.g., plastic such as polyimide).

Turning to FIG. 1B, the coil 102 has a longitudinal axis 114 extending through a center of the windings 108 from a side of the coil 102 proximate the first coil end 110 to an opposite side of the coil proximate the second coil end 112. A cross-sectional dimension of the windings 108 is based on a coil shape of the conductive material forming the windings 108. The coil shape of the windings 108 is defined by a winding of the windings 108 being cut by a plane including the longitudinal axis 114 of the windings 108. The coil shape may comprise a flat wire wound coil, a stable winding, a round wire wound coil, outer-outer coil, or other winding shape. The largest cross-sectional dimension of the coil 102 is given by diametrically opposed points of the windings having the largest distance between. Suppose the coil shape of the windings is approximately elliptical; then the largest cross-sectional dimension of the windings 108 is the major axis of the ellipse.

The lead structures 104, 106 are formed of a conductive material, such as copper, palladium, gold, silver, or other appropriate conductive metal or metal alloy with similar properties, and can be formed of the same material as the coil 102. For example, the lead structures 104, 106 are formed of a copper sheet. Each lead structure 104, 106 has opposing surfaces. In the example of FIGS. 1A and 1B, the ends of the coil are coupled to respective lead structure surfaces 116 and 118. As one example, each of the lead structures 104, 106 has a perimeter that that defines a shape of the respective lead structures (e.g., rectangular, chamfered rectangular, T-shaped, L-shaped, E-shaped, circular, etc.).

As described herein, each opposing surface of the respective lead structures 104, 106 can have a two-dimensional shape. Additionally, one or both of the lead structures 104, 106 can be formed (e.g., by bending) into three-dimensional shapes, which can vary according to application requirements where the inductor device is to be mounted. Returning to FIG. 1A, the lead structure 104 includes, for example, a first dimension 120 and a second dimension 122. As one example, the second dimension 122, which is less than the first dimension, can represent the width of the lead structure 104. In other examples, any of the respective dimensions 120 and 122 can be referred to as being a width or a length thereof without distinction. The smaller dimension 120 or 122 of the lead structures 104, 106 is greater than a largest cross-sectional dimension of the winding 108. The lead structures 104, 106 can also have a thickness that is the same or approximates the cross-sectional dimension of the windings 108.

The coil ends 110, 112 are attached to surfaces 116, 118 of the lead structures 104, 106, respectively, using a suitable technique or mechanism. For example, the first coil end 110 is laser-welded to a point on the lead structure surface 116 and the second coil end 112 is laser-welded to a point on the lead structure surface 118. In another example, the coil ends and surfaces can be formed as a monolithic structure, such as by laser cutting the windings and lead structures from a common sheet of material. The coil ends 110, 112 are attached to the lead structures 104, 106 so that the lead structures 104, 106 are spaced apart from the longitudinal axis 114 by a distance. For example, the first lead structure 104 is separated from the longitudinal axis 114 by a first distance 124 and the second lead structure 106 is separated from the longitudinal axis 114 by a second distance 126, as shown in FIG. 1B. The first and second distances 124 and 126 can be the same or different distances. While two lead structures 104, 106 are described in the example of FIGS. 1A and 1B, the device 100 may include a single lead structure, such as either the first lead structure 104 or the second lead structure 106.

In some examples, the first lead structure surface 116 of the first lead structure 104 and/or the second lead structure surface 118 of the second lead structure 106 has a three-dimensional shape by including one or more bends. As shown in FIG. 1C, the first lead structure surface 116 of the first lead structure 104 is bent. For example, the first lead structure 104 includes a first portion 128 and a second portion 130 and the second lead structure 106 includes a first portion 132 and a second portion 134. The first portions 128, 132 can reside in a common plane. The second portions 130, 134 extend from the first portions 128, 132, respectively, and are bent at respective angles relative to the plane. The longitudinal axis 114 can be oriented at a respective angle relative to the plane ranging from parallel to orthogonal.

While the first portions 128, 132 are described as residing a single plane, but may each reside in a different plane and/or have different angles. For example, the first portion 128 and the second portion 130 of the first lead structure 104 define a first angle and the first portion 132, and the second portion 134 of the second lead structure 106 define a second angle that is different than the first angle.

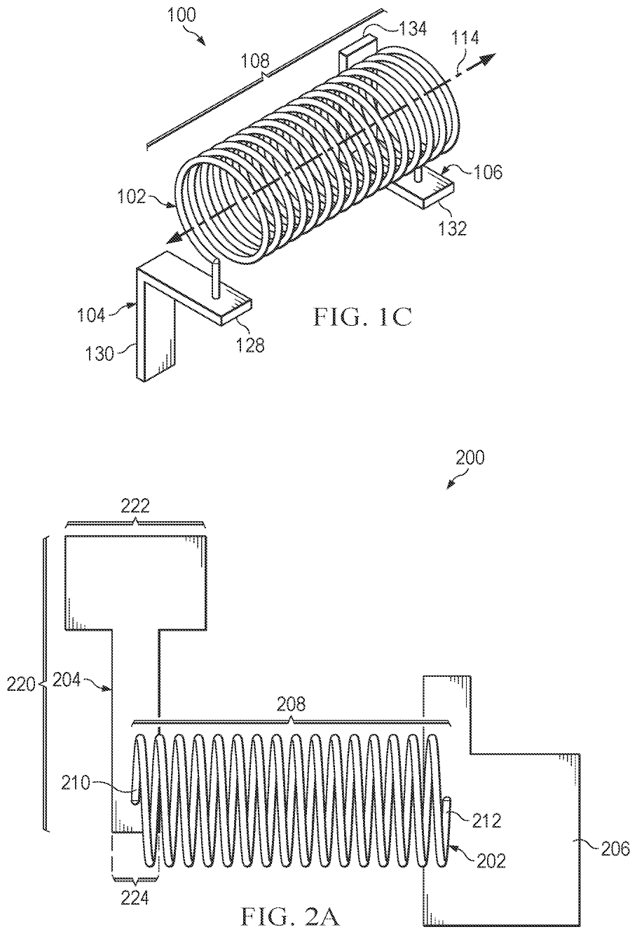

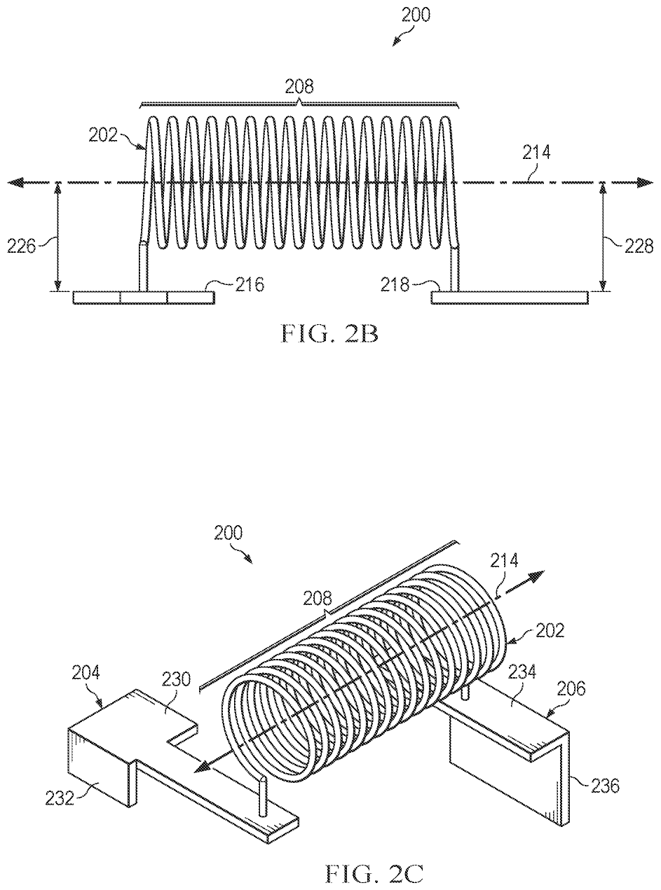

FIG. 2A illustrates a top view of a device 200 having a coil, the first lead structure 204 and a second lead structure 206. The lead structures 204, 206 have lead structure shapes such as a rectangular shape, a T-shape, and an L-shape. For example, the first lead structure 204 has a T-shape and the second lead structure 206 has an L-shape. The coil 102 includes a number of windings 208 arranged between a first coil end 210 and a second coil end 112.

FIGS. 2A and 2B are top and side views showing another example inductor device 200 that includes a coil 202 and respective lead structures 204 and 206. As shown in FIG. 2B, the coil 202 has a longitudinal axis 214 extending through a center of the windings 208 from a side of the coil 202 proximate a first coil end 210 to an opposite side of the coil proximate a second coil end 212. A cross-sectional dimension of the windings 208 is based on a shape of the conductive material forming the windings 208. Each lead structure 204, 206 has a lead structure shape is defined by a perimeter of the lead structure surface, such as a first lead structure surface 216 of the first lead structure 204 and a second lead structure surface 218 of the second lead structure 206.

As described herein, a width of the lead structures 204, 206 is greater than a largest cross section of the windings 208. As shown in FIG. 2A, for example, the width is based on a span of the lead structure surface in a given direction, such as any of dimensions 220, 222 or 224 of lead structure the first lead structure 104. The width thus can be defined by a dimension of the respective lead structure 204, 106, as described with respect to FIGS. 1A and 1B. As one example, the width is shortest dimension of the lead structure surface, shown as dimension 224. The lead structures 204, 206 can also have a thickness that is the same or approximates the cross-sectional dimension of the windings 208.

The coil ends 210, 212 are attached to the lead structures 204, 206 so that the lead structures 204, 206 are spaced apart from the longitudinal axis 214 by a distance. For example, the first lead structure 204 is separated from the longitudinal axis 214 by a first distance 226 and the second lead structure 206 is separated from the longitudinal axis 214 by a second distance 228, as shown in FIG. 2B.

As shown in FIG. 2C, the first lead structure surface 216 of the first lead structure 204 and/or the second lead structure surface 218 of the second lead structure 206 can be formed as three-dimensional structures, such as having one or more bends. For example, the first lead structure 204 includes a first portion 230 and a second portion 232, and the second lead structure 206 includes a first portion 234 and a second portion 236. The first portions 230, 234 can be coplanar or reside in planes that are spaced apart from each other. The second portions 232, 236 extend from the first portions 230, 234, respectively, and are bent at angles relative to the portions from which they extend. The longitudinal axis 214 is oriented at a respective angle relative to the plane ranging from parallel to orthogonal.

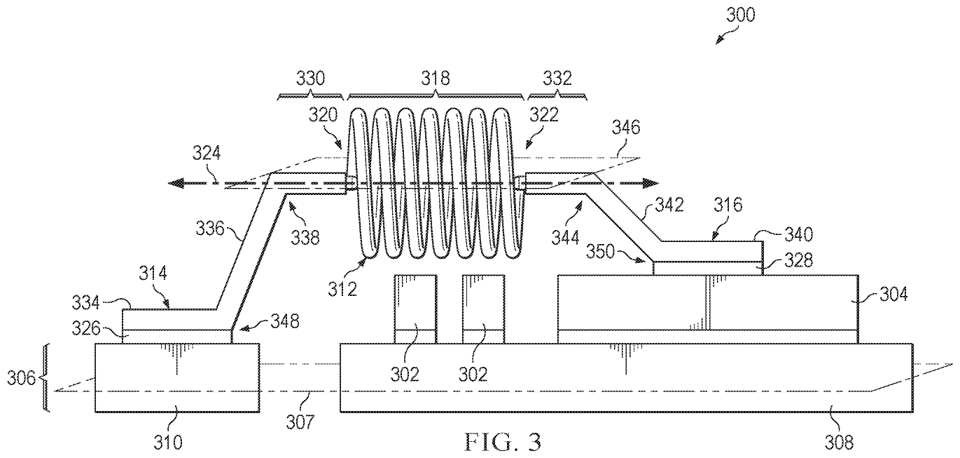

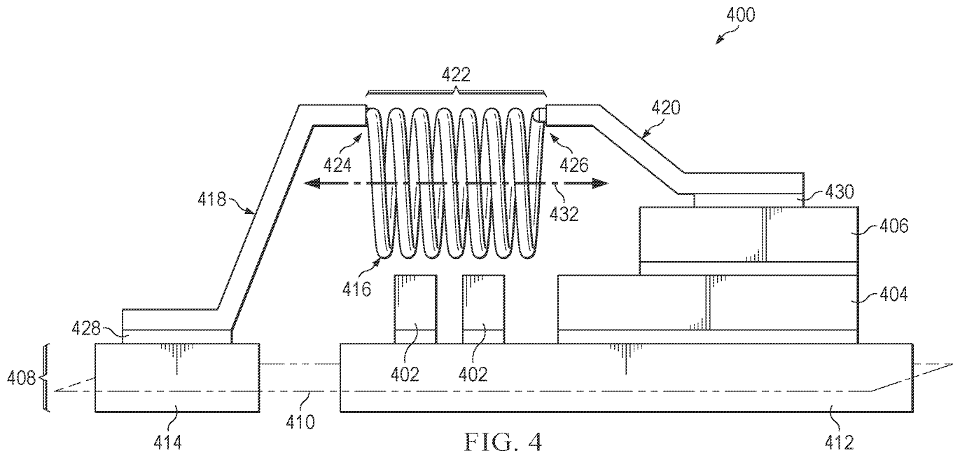

The examples given in FIGS. 1A-1C and 2A-2C are not intended to be limiting. The components (e.g., coils, coil ends, lead structures) and/or configurations (e.g., bends, lead structure shapes, longitudinal axes, width, distances) are interchangeable in the examples given in FIGS. 1A-1C and 2A-2C. For example, any of the devices described with respect to FIGS. 1A-1C and 2A-2C can be used in circuits as will be discussed with respect to FIGS. 3-7. Accordingly, the description of the FIGS. 3-7 can refer back to the examples of FIGS. 1A-1C and 2A-2C.

FIG. 3 illustrates a first example of a circuit 300 having one or more components 302 and an IC die 304 mounted on a substrate 306. Examples of the components 302 include transistors, drivers, capacitors, controllers, etc. The substrate 306 defines a plane 307 extending through the substrate 306. In some examples, the substrate 306 is a leadframe having a die pad 308 spaced apart from a lead 310. The leadframe is formed of an electrically conductive material. The die pad 308 provides an electrical connection between the die 304 and the lead 310. The lead 310 is exposed to an external environment to enable the components 302 to be electrically coupled with one or more other electrical components external to the circuit 300.

The circuit 300 includes a coil 312 is suspended over the components 302 by a first lead structure 314 and a second lead structure 316. For example, the lead structure can be implemented according to the lead structures 104, 106 or 204, 206. The coil 312 includes a number of windings 318 arranged between a first coil end 320 and a second coil end 322 of the coil 312. The windings 318 are formed of a conductive material. A longitudinal axis 324 extends through a center of the windings 318 from a side of the coil 312 proximate the first coil end 320 to an opposite side of the coil 312 proximate the second coil end 322.

The first coil end 320 is attached to the first lead structure 314 and the second coil end 322 is attached to the second lead structure 316. The first lead structure 314 is electrically coupled to the substrate 306 respective a first terminal 326. The second lead structure 316 is electrically coupled to the die 304 via a terminal or pad 328 of the die. The terminal can be coupled to circuitry within the die 304 be coupled to the substrate through a connection (e.g., a through silicon via) extending through the die 304 The die 304 can also be coupled to substrate 306 via one or more terminals on die pad 308 of substrate 306. For example, the first terminal 326, mounted on the lead 310, is a leadframe terminal and the second terminal 328, mounted on the die 304, is a die terminal. In the example of FIG. 3, the first terminal 326 and the second terminal 328 are spaced different distances from the plane 307 of the substrate 306. Despite the first terminal 326 and the second terminal 328 being spaced different distances from the plane 307, the longitudinal axis 324 can be parallel to the plane 307. The lead structures 314, 316 facilitate different arrangements of the coil that are not limited to areas of the circuit 300 where the coil 312 is attached at the same distance from the plane 307 defined by the substrate 306. Instead, the lead structures 314, 316 can be electrically coupled to the first terminal 326 and the second terminal 328, which are at different distances from the plane 307, thereby facilitating numerous design configurations without requiring additional space.

The first lead structure 314 has a first lead structure dimension 330 and the second lead structure 316 has a second lead structure dimension 332. For example, the first lead structure 314 includes a first portion 334, a second portion 336, and a third portion 338 defined by bends in the first lead structure 314. The first portion 334 of the first lead structure 314 is attached to the first terminal 326 and extends parallel to the plane 307 of the substrate 306. The second portion 336 of the first lead structure 314 extends away from the plane of the substrate 306 at an angle towards the coil 312. The third portion 338 of the first lead structure 314 is coupled to the first coil end 320 and extends parallel to the plane 307 of the substrate 306. Accordingly, the first portion 334 and the third portion 338 constitute end portions of the first lead structure 314 that are different distances from the plane 307 of the substrate 306.

In a similar manner, the second lead structure 316 includes a first portion 340, a second portion 342, and a third portion 344 arranged with respect to each other by bends in the second lead structure 316. The first portion 340 of the second lead structure 316 is coupled to the second terminal 328 and extends parallel to the plane 307 of the substrate 306. The second portion 342 of the second lead structure 316 extends away from the plane 307 of the substrate 306 at an angle towards the coil 312. The third portion 344 of the second lead structure 316 is attached to the second coil end 322 and extends parallel to the plane 307 of the substrate 306.

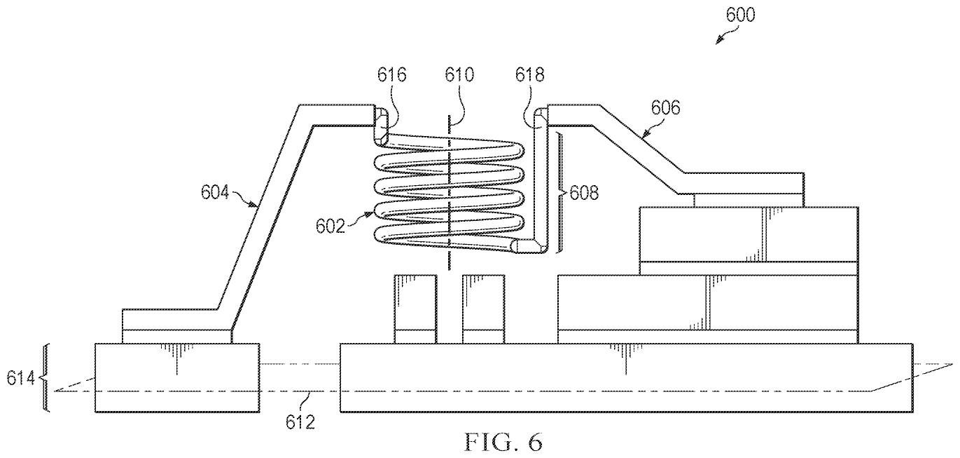

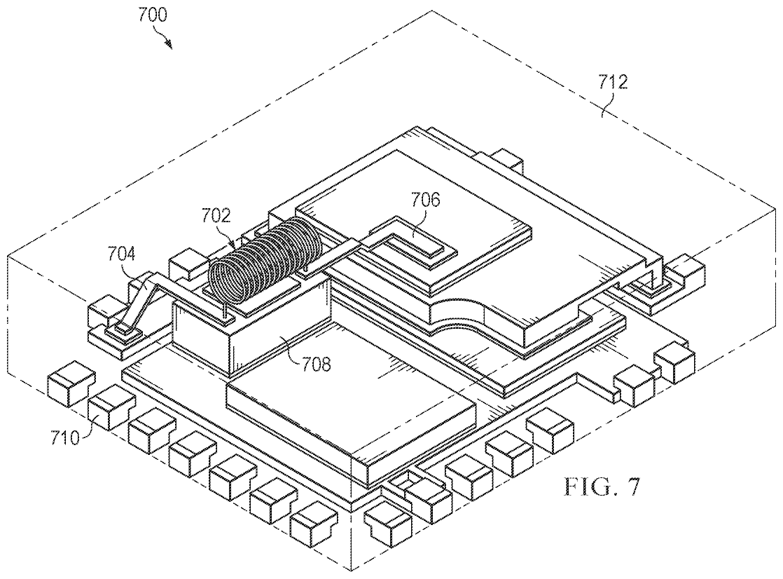

In some examples, the coil 312 is suspended between the lead structures 314, 316 such that the respective third portions 338, 344 are vertically aligned with (e.g., coplanar with) the longitudinal axis 324 extending through the windings 318 such that the longitudinal axis 324 is in a plane 346 with the third portions 338, 344. In other examples the longitudinal axis 324 may be above or below the plane 346 of the third portions 338, 344, as shown in FIGS. 4 and 6.

The first lead structure 314 has a first bend 348 at a first angle relative to the plane 307 and the second lead structure 316 has a second bend 350 at a second angle relative to the plane 307. The first bend 348 is formed where the first portion 334 meets the second portion 336 of the first lead structure 314. The second bend 350 is formed where the first portion 340 meets the second portion 342 of the second lead structure 316. The first angle of the first bend 348 is different from the second angle of the second bend 350 as a result of the first lead structure 314 being attached to the first terminal 326 and the second lead structure 316 being attached to the second terminal 328, which are spaced different distances from the plane 307.

The first lead structure 314 has a width (not shown in FIG. 3, but see FIG. 1A or 2A) that is greater than a largest cross-sectional dimension of the windings 318. The second lead structure 316 also has width that is greater than the largest cross-sectional dimension of the windings 318. In this example, the lead structure widths 330, 332 are defined relative to the respective third portions 338, 344, but may be defined relative to a dimension of the respective first portions 334, 340 or second portions 336, 342.

As another example, FIG. 4 illustrates a multi-die configuration of a circuit 400 including one or more components 402, a first die 404, and a second die 406 mounted on a substrate 408. In FIG. 4, the second die 406 is stacked on the first die 404. The first die 404 and the second die 406 are coupled, for example, via bond pads or terminals, coupled to circuitry within (not shown) the respective die. As another example, a lead of the first die 404 can be coupled to circuitry of the second die 406 through a connection provided by a through silicon via that extends through the first die 404 to couple to a die pad of the second die 406 through silicon via.

The substrate 408 defines a plane 410 extending through the substrate 408. The substrate 408 can be a leadframe having a die pad 412 and one or more leads 414. The first die 404 is mounted on the die pad 412 and the second die 406 is separated from the die pad 412 by the first die 404 on which the second die is mounted. The die pad 412 provides electrical connections between the first die 404 and respective terminals of the substrate 408.

A coil 416 is suspended over the component(s) 402 by a first lead structure 418 and a second lead structure 420. The coil 416 includes a number of windings 422 arranged between a first coil end 424 and a second coil end 426. A longitudinal axis 432 extends through a center of the windings 422 from a side of the coil 416 proximate the first coil end 424 to an opposite side of the coil 416 proximate the second coil end 426. The first coil end 424 is coupled to the first lead structure 418 and the second coil end 426 is coupled to the second lead structure 420 to provide an inductor device. The first lead structure 418 and the second lead structure 420 are electrically coupled to the substrate 408 respective first terminal 428 and via die terminal 430, through the first die 404 and the second die 406 to the substrate 408. For example, the first terminal 428 is a leadframe terminal and the second terminal 430 is a die terminal. Using the lead structures 418, 420, the coil 416 is mounted over the component(s) 402 to accommodate the circuit 400 even though the first terminal 428 and the second terminal 430 are spaced different distances from the plane 410 of the substrate 408.

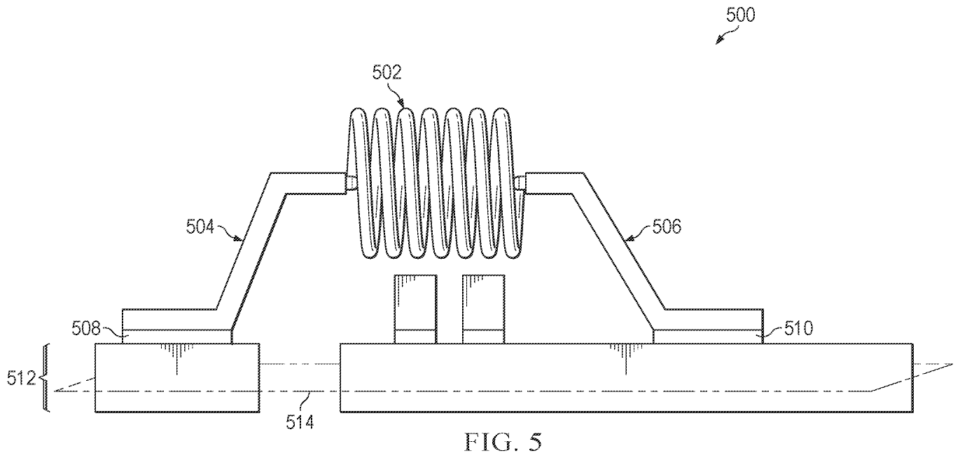

Although the lead structures 418, 420 facilitate suspending the coil 416 in a configuration in which the first terminal 428 and the second terminal 430 are spaced different distances from the plane 410 of the substrate 408, the lead structures 418, 420 may also be used for a configuration in which the first terminal 428 and the second terminal 430 are spaced the same distance from the plane 410, as shown in FIG. 5.

As a further example, FIG. 5 illustrates a circuit 500 having a coil 502 suspended between a first lead structure 504 and a second lead structure 506. The circuit 500 also includes a first terminal 508 and a second terminal 510 mounted on a substrate 512 that defines a plane 514. In the example of FIG. 5, distal ends of the lead structures 504, 506 are mounted to respective terminals 508 and 510 that are spaced the same distance from the plane 514 in a vertical direction that extends from the substrate 512 to the coil 502.

As shown with respect to the circuits 300 of FIG. 3, 400 of FIG. 4 and 500 of FIG. 5, lead structures accommodate various configurations regardless of the height of terminals relative to a substrate of the circuits. Therefore, using the lead structures described herein, components are able to be arranged on the circuit to accommodate spacing concerns without reference to the relative distances between the terminals and a plane defined by the substrate and/or a longitudinal axis of the coils.

Additionally, the lead structures described herein enable different configurations of coils. FIG. 6 illustrates a circuit 600 having an example coil 602 having alternative coil configuration. The coil 602 is coupled to terminals of the circuit by a first lead structure 604 and a second lead structure 606, which are configured to suspend the coil over substrate 614. The coil 602 has a number of windings 608 that define a longitudinal axis 610 extending approximately orthogonal to a plane 612 defined by a substrate 614. The coil 602 has a first coil end 616 and a second coil end 618 spaced the same distance apart from the plane 612 of the substrate 614. In one example, the coil ends 616, 618 are also arranged at diametrically opposed points relative to the central axis 610.

FIG. 7 illustrates an example of a packaged circuit 700 having a coil 702. The coil 702 extends between a first lead structure 704 and a second lead structure 706. In some examples, the packaged circuit 700 is an integrated circuit and a system on chip. The packaged circuit 700 includes component(s) 708, a die, and a lead 710. The packaged circuit 700 is at least partially encapsulated in a molding compound 712 to form a housing. For example, the molding compound 712 encapsulates a top side of the packaged circuit 700. The molding compound 712 is formed of an insulating material, such as organic resins, inorganic resins, or other suitable material.

While the examples in FIGS. 1A-7 illustrate two lead structures, more or fewer than two lead structures may be used to support a coil. For example, a first coil end of a coil may be attached to a lead structure that is affixed to a first terminal, while a second coil end of the coil is attached directly to a second terminal.

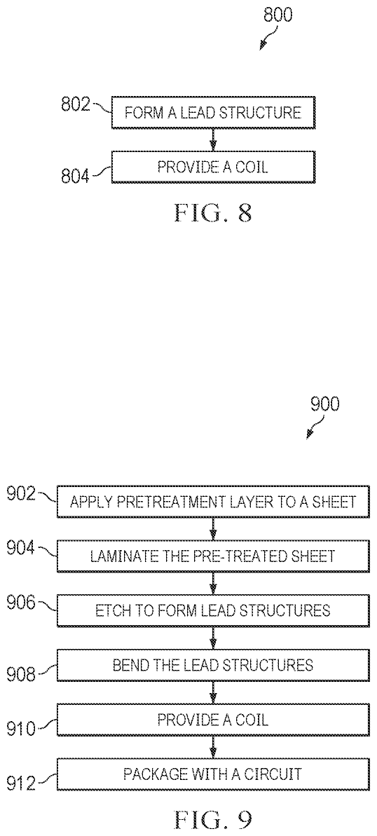

FIG. 8 illustrates a flowchart of a first example method 800 for fabricating an inductor device. The method 800 can be used to form any of the inductor devices 100, 200, 312, 416, 502, 602, 702 described herein. Accordingly, the description of FIG. 8 can also refer to the descriptions of FIGS. 1A-7. At 802, the method 800 includes forming a lead structure having a lead structure surface, defining a plane, having a lead structure length and a lead structure width. For example, the lead structure is a first lead structure that includes a first portion, a second portion, and a third portion defined by bends in the first lead structure. The lead structure has a width that is a dimension of a shape of the lead structure surface.

The method 800 can also include forming one or more lead structures in addition to a first lead structure, such as a second lead structure. The first lead structure has a first lead structure surface that defines a first shape and the second lead structure has a second lead structure surface that defines a second shape. In some examples, the shapes of the first lead structure and the second lead structure are different. The first lead structure has a first lead structure width and the second lead structure has a second lead structure width. In some examples, the first lead structure width and the second lead structure width are different.

At 804, the method 800 includes providing a coil of electrically conductive material having first and second coil ends and a number of windings of the electrically conductive material extending between the first and second coil ends. The lead structure width is greater than a largest cross sectional dimension of the windings (e.g., taken through a portion of the winding). In an example inductor device having first and second lead structures, the first lead structure width and the second lead structure width are each greater than the largest cross sectional dimension of the windings.

The coil has a longitudinal axis extending through the windings. The longitudinal axis is oriented at an angle relative to the plane that includes the lead structure surface(s). The angle ranges from parallel to orthogonal to the plane that includes the lead structure surface(s). In some examples, the distances between the first and second coil ends and longitudinal axis are different. Using at least one lead structure facilitates electrically coupling the coil ends to terminals at different heights relative to the substrate, thereby facilitating numerous design configurations for the coil without requiring additional terminals, and the corresponding additional space, for affixing the coil ends to terminals at the same height relative to the substrate.

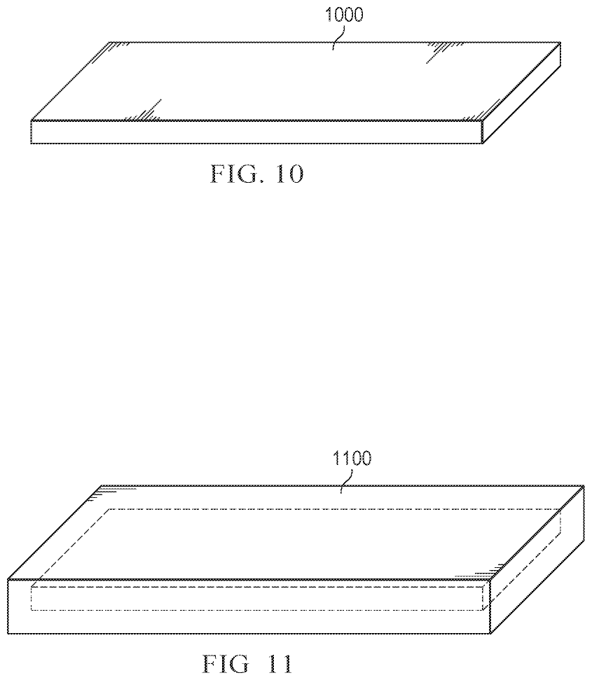

FIG. 9 illustrates a flowchart of an example method for forming a circuit having an inductor device including one or more lead structures and a coil. At 902, the method 900 includes applying a pretreatment layer to a conductive sheet. For example, FIG. 10 illustrates an example conductive sheet 1000 formed of a conductive material, such as copper. FIG. 11 shows an example of a treated conductive sheet 1100, as applied at 902.

At 904, the method 900 includes laminating the treated conductive sheet 1100. For example, FIG. 12 shows and example of a laminated conductive sheet 1200 formed at 904.

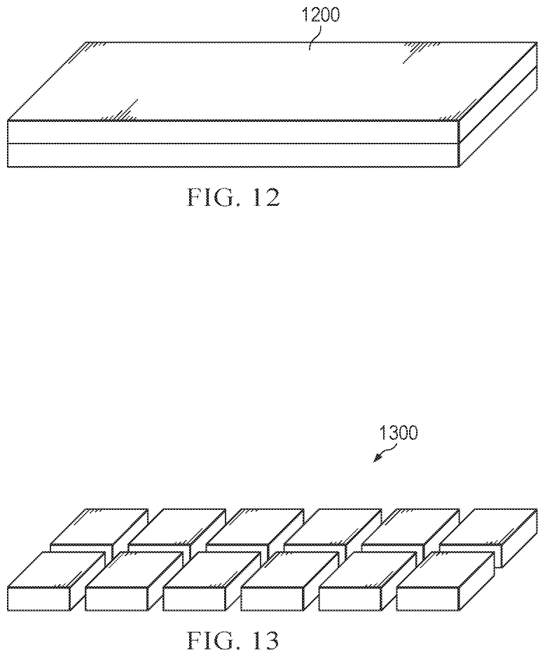

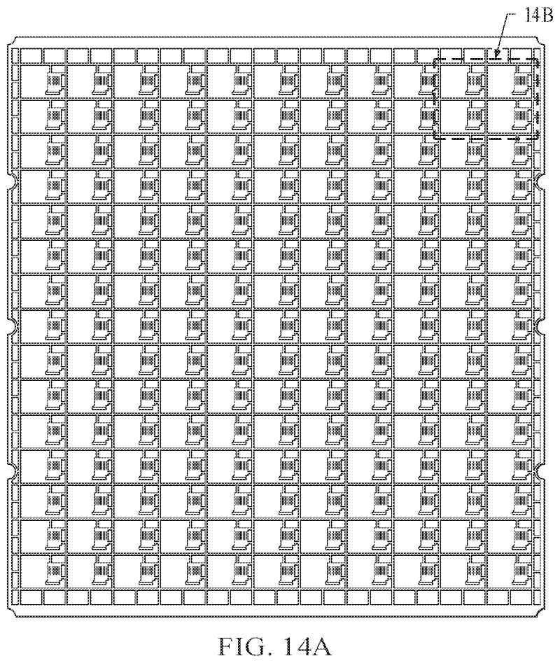

At 906, the method 900 includes etching the laminated conductive sheet to form an arrangement of lead structures. For example, FIG. 13, shows an example of part of sheet that includes lead structures 1300 formed responsive to etching the laminated conductive sheet 1200 of FIG. 12. The etching can be performed at 906 to form the lead structures of with respective surfaces that device a lead structure shape, such as a rectangular shape, a T-shape, or an L-shape.

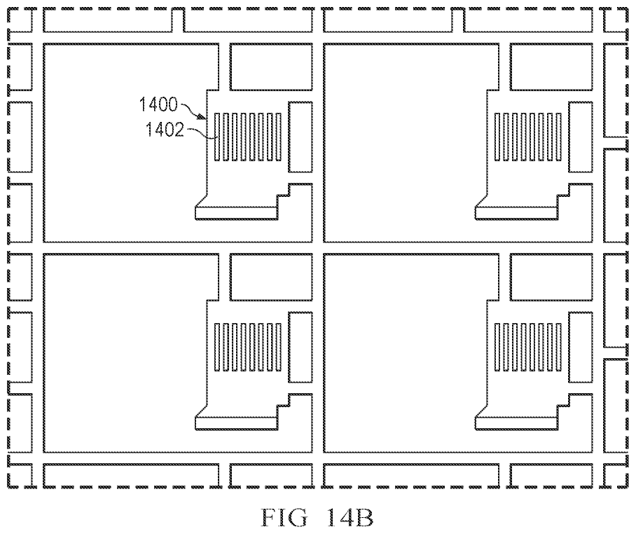

At 908, the method 900 includes bending a first portion of the lead structure at an angle away from a second portion of the lead structure that extends along the plane parallel to the longitudinal axis. For example, FIG. 14A shows an example sheet of lead structures responsive to the bending at 908. The bending at 908 forms a bend 1400 in the lead structure, shown in FIG. 14B. The bend 1400 allows the lead structure to be customized to the layout of a circuit. In particular, one or more portions of each lead structure is bent to suspend the coil over one or more components of the circuit and electrically couple the coil to terminals having various heights relative to the substrate of the circuit. The shape and dimensions of the lead structures provides additional mechanical support to maintain the position of the coil in the circuit where mounted.

At 910, the method 900 includes providing a coil to a lead structure to form a device. The coil has a first coil end separated from a second coil end by a number of windings. The coil has a longitudinal axis extending through the windings. As described herein, the coil can be coupled to one or more lead structures. The coil can be formed with the lead structures as a monolithic structure from same sheet of conductive material 1000. For example, the set of lead structures 1300 etched from the laminated conductive sheet 1200 also include a length of the electrically conductive material coupled to the lead structures (e.g., an elongated projection, such as in the form of a filament or wire). The coil can be formed by winding the length of electrically conductive material (e.g., around a mandrel) to provide a desired geometry and number of windings. In this manner, the coil is formed from a portion of the laminated conductive sheet 1200, and the coil can be formed as a unitary monolithic structure with the lead structures. In other examples, the coil is formed separately from the lead structure and is then affixed to the lead structure (e.g., by welding). In such an example, providing the coil includes attaching the coil to the lead structure, for example, by soldering the first coil end to the lead structure surface. FIGS. 1A-7 show examples of some different configurations of inductor devices that can be provided at 910.

At 912, the method 900 includes coupling the inductor device to a circuit and packaging the inductor device and circuit including a terminal. For example, at 912, the packaging of the inductor device includes coupling the lead structures to respective terminals of the circuit. The lead structures can be bent (at 908) at respective angles to position the distal end portions of the lead structures at the terminals where they can be coupled (e.g., by soldering). The packaging may include encapsulating the circuit in a molding compound, such as an epoxy or other material, such as shown in FIG. 7.

In this description, unless otherwise stated, “about,” “approximately” or “substantially” preceding a parameter means being within +/−10 percent of that parameter. Modifications are possible in the described embodiments, and other embodiments are possible, within the scope of the claims.

What is claimed is:

1. A device comprising:
a lead structure, of an electrically conductive material, having a lead structure width; and
a coil, of the electrically conductive material, having first and second coil ends and a number of windings of the electrically conductive material extending between the first and second coil ends, wherein the lead structure width is greater than a largest cross sectional dimension of the windings.

2. The device of claim 1, wherein the lead structure has one of a rectangular shape, a T-shape, and an L-shape.

3. The device of claim 1, wherein:
the coil has a longitudinal axis extending through a center of the windings, and a plane extends through at least a portion of the lead structure, and
the lead structure is spaced apart from the longitudinal axis and has first portion along the plane and a second portion extending from the first portion bent at an angle relative to the plane, and
the longitudinal axis is oriented at a respective angle relative to the plane ranging from parallel to orthogonal.

4. The device of claim 1, wherein the lead structure is a first lead structure, the lead structure width is a first lead structure width, the coil has a longitudinal axis extending through a center of the windings, and the device further comprises:
a second lead structure, of the electrically conductive material, at the second coil end, wherein the second lead structure has a second lead structure width greater than the largest cross sectional dimension of the windings.

5. The device of claim 4, wherein the first lead structure has a first bend at a first angle relative to the longitudinal axis and the second lead structure has a second bend at a second angle relative to the longitudinal axis.

6. The device of claim 4, wherein end portions of the first and second lead structures are spaced different distances from the longitudinal axis.

7. The device of claim 1, further comprising:
a substrate supporting a circuit, wherein a substrate surface of the substrate defines a plane extending through the substrate;
a terminal electrically coupled to the lead structure; and
a molding compound encapsulating the device.

8. A circuit comprising:
a substrate supporting the circuit, wherein a substrate surface of the substrate defines a plane extending through the substrate;
a terminal;
a lead structure of an electrically conductive material, having a lead structure width, coupled to the terminal; and
a coil, of the electrically conductive material, having first and second coil ends and a number of windings of the electrically conductive material extending between the first and second coil ends, the first coil end at a surface of the lead structure, wherein the lead structure width is greater than a largest cross sectional dimension of the windings.

9. The circuit of claim 8, wherein the lead structure has first portion extending parallel to the plane and a second portion bent at an angle away from the plane.

10. The circuit of claim 8, wherein the substrate is a leadframe, and wherein the terminal includes a leadframe terminal of the leadframe.

11. The circuit of claim 10, further comprising:
a die mounted on the leadframe, and the terminal includes a die terminal.

12. The circuit of claim 8, wherein the lead structure is a first lead structure, the terminal is a first terminal, the lead structure width is a first lead structure width, and the circuit further comprises:
a second lead structure at the second coil end, wherein the second lead structure has a second lead structure width greater than the largest cross sectional dimension of the windings; and
a second terminal spaced apart from the first terminal, wherein the second lead structure is coupled to the second terminal.

13. The circuit of claim 12, wherein the first terminal and the second terminal are spaced different distances from the plane.

14. The circuit of claim 12, wherein the first lead structure has a first bend at a first angle relative to the plane and the second lead structure has a second bend at a second angle relative to the plane.

15. The circuit of claim 12, wherein the substrate is a leadframe, wherein the first terminal is a leadframe terminal of the leadframe, and wherein the first lead structure is coupled to the leadframe terminal, the circuit further comprising:
a die mounted on the leadframe, wherein the second terminal is a die terminal of the die, and the second lead structure is coupled to the die terminal.

16. The circuit of claim 15, wherein the circuit is one of an integrated circuit and a system on chip and encapsulated in a molding compound.

17. The circuit of claim 8, wherein the coil has a longitudinal axis that is oriented at a respective angle relative to the plane ranging from parallel to orthogonal to the plane.

18. A method for forming a device, the method comprising:
forming a lead structure having a lead structure surface defining plane having a lead structure length and a lead structure width; and
providing a coil, of electrically conductive material, having first and second coil ends and a number of windings of the electrically conductive material extending between the first and second coil ends, wherein the lead structure width and the lead structure length are greater than a largest cross sectional dimension of the windings.

19. The method of claim 18, wherein providing the coil includes attaching the coil to the lead structure by soldering the first coil end to the lead structure surface,
the coil has a longitudinal axis extending through the windings thereof, and
the longitudinal axis is oriented at an angle relative to the plane ranging from parallel to orthogonal to the plane.

20. The method of claim 18, wherein:
the lead structure is formed from a conductive sheet of the electrically conductive material, and
the method further comprises winding the electrically conductive material from a portion of the conductive sheet to provide the coil.

21. The method of claim 18, wherein:
the lead structure surface has a shape that is one of a rectangular shape, a T-shape, and an L-shape, and
forming the lead structure includes etching or cutting a conductive sheet of the electrically conductive material to form the shape of the lead structure.

22. The method of claim 18, wherein the windings define a longitudinal axis, the method further comprises:
bending a first portion of the lead structure at an angle away from a second portion of the lead structure that extends along the plane parallel to the longitudinal axis to form a bend in the lead structure.

23. The method of claim 22, further comprising:
coupling the lead structure to a terminal of a circuit, in which the angle is configured to bend the lead structure toward the terminal.

24. The method of claim 18, wherein the lead structure is a first lead structure, the lead structure width is a first lead structure width, the lead structure surface is a first lead structure surface, and the method further comprises:
forming a second lead structure having a second lead structure width of a second lead structure surface, wherein the second lead structure width is greater than the largest cross sectional dimension of the windings, wherein the second coil end is at the second lead structure surface.

25. The method of claim 24, wherein providing the coil includes attaching the coil to the lead structure by soldering the second coil end to the second lead structure surface.

26. The method of claim 24, wherein end portions of the first and second lead structures are different distances from the plane.
